(19) United States
(12) Patent Application Publication
(10) Pub. No.: US 2015/0241772 A1
(43) Pub. Date: Aug. 27, 2015

(54) DOUBLE COATED NEGATIVE-WORKING DRY-FILM PHOTORESIST

(71) Applicant: ZHUHAI DYNAMIC TECHNOLOGY OPTICAL INDUSTRY CO., LTD., Zhuhai City, Guangdong (CN)

(72) Inventors: Dekai Loo, Zhuhai (CN); Weiguo Yang, Zhuhai (CN); Yan Dong, Zhuhai (CN)

(73) Assignee: Zhuhai Dynamic Technology Optical Industry Co., Ltd., Zhuhai, Guangdong (CN)

(21) Appl. No.: 14/423,933

(22) PCT Filed: Aug. 2, 2013
(86) PCT No.: PCT/CN2013/080692

§ 371 Date: Feb. 25, 2015

(30) Foreign Application Priority Data
Aug. 27, 2012 (CN) 201210308978.5

(51) Int. Cl. G03F 7/038; G03F 7/11

(52) U.S. Cl. CPC G03F 7/0382; G03F 7/11; G03F 7/0384

(57) ABSTRACT

A double coated negative-working dry-film photoresist in the application of printed circuit board is discussed wherein the dry film contains flexible carrier film, flexible cover film, photopolymerizable composition layer, and intermediate protective layer. The character is as following: the intermediate protective layer is between flexible carrier film and photopolymerizable composition layer, transparent, colorless, soluble in the developer solution of photopolymerizable composition, adhesion between both photopolymerizable composition layer and flexible carrier film, but the adhesion with the photopolymerizable composition layer is larger than that with the flexible carrier film. The intermediate protective layer is polyvinyl alcohol (PVA) or carboxyl-containing polymers. Photopolymerizable compositions contain polymeric binder, free-radical photoinitiator, addition-polymerizable monomer, thermo-polymerization inhibitor. In order to further improve the performance, some other ingredients can be added, such as plasticizer, dye, adhesion promoter et al. The present invention enhances the resolution of the dry-film photoresist and lowers the cost of the carrier film.

### TECHNICAL FIELD

The present invention involves a double coated negative-working dry-film photoresist. The character is that there are two coated layers between flexible carrier and cover films. One of the two layers is polymeric protective photo-insensitive intermediate layer and the other layer is photoresist of photo-sensitive material.

### TECHNICAL BACKGROUND

Dry-film photoresist is required to be used in the manufacture of printed circuit board (PCB). Based on the consideration of environment and production cost, most of dry-film photoresist is aqueous-developable.

Generally, aqueous-developable dry-film photoresist consists of photoresist thin-film covered by two supporting (protective) layers, The thickness of the carrier film is 15-25 micrometers and the photoresist thin-film is 12-75 micrometers, as shown in FIG. 1.

The suitable materials for supporting layers can be selected from variety of polymers, such as polyamide, polyene, and polyester, including but not limited to those polymers. The supporting layer 1 is normally named as carrier film and supporting layer 2 is normally named as cover film. The thickness of the supporting layers must be uniform and not contaminated with any particles to guarantee the quality and high pass-yield in the PCB production. Moreover, the carrier film must be transparent and colorless to guarantee the exposing level.

Generally, such dry film photoresist is made by applying the solvated resist material to a carrier film, such as a transparent polyester thin-film, and then evaporating the solvent, and finally covered by a polyethylene thin-film, to produce the dry film, as shown in FIG. 1.

There are two types of dry-film photoresist: positive-working and negative-working. Positive-working dry-film is that the portion exposed under UV-light is changed from insoluble to soluble in the developing solution. Contrary, negative-working dry-film is that the portion under UV-light exposing is changed from soluble to insoluble in the developing solution.

The negative-working dry-film photoresist composition is soluble in an alkaline aqueous develop solution. The aforementioned exposed and cured areas is insoluble in the alkaline aqueous develop solution. In typical use as a negative-working photoresist, a dry-film photopolymerizable composition is applied to a copper-clad substrate along with the carrier by heat and pressure, exposed in a certain areas through the carrier film to UV radiation or laser radiation that will cure the exposed areas, and then the carrier film is removed and washed with an alkaline aqueous solution to remove the unexposed film from the copper. The exposed copper surface can then be removed in etching solutions leaving the protect area under the cured photopolymerizable composition, which finally stripped by an aqueous alkaline solution to form the electrical circuit.

The application procedures of the positive-working dry-film photoresist are similar with that of negative-working dry-film photoresist. However, the positive-working photoresist composition is insoluble in an aqueous alkaline develop solution, After exposed under UV or laser light, the exposed part is changed into soluble in the aqueous alkaline develop solution. Due to this key difference, there are huge differences of the chemical ingredients of the photoresist compositions, manufacture methods and requirements, and application procedures and conditions between the positive-working and negative-working photoresists.

The use of dry-film photoresist aforementioned in the manufacture of PCB and the positive-working and negative-working photoresist are apparent to those skilled in the art.

It is required to use the carrier film in the manufacture of the traditional negative-working dry-film. Firstly, it works as a barrier to oxygen, which is a well know radical inhibitor. In the presence of oxygen the photospeed of the radiation will be slow down substantially. Secondly, the carrier film protects the photoresist layer in the storage and transportation. Most important, the carrier film is required between the artwork (negative) and the photoresist layer in the radiation exposing process. Otherwise, the artwork (negative) and the photoresist layer in the radiation exposing process would be adhered together in the direct contact to damage both artwork and photoresist layer. Since the radiation must be though the carrier film, the carrier film must be transparent and colorless to insure the photospeed and the expose quality. The high requirements of the carrier film will increase the cost of the manufacture. Moreover, light scattering would occur to lower the resolution when the actinic radiation passes through the carrier film of thickness as of 15 to 25 micrometers.

### SUMMARY

According to the present invention there is provided an aqueous-developable negative-working double coated dry-film photoresist, comparing to the traditional dry-film photoresist the improvement wherein enhances the resolution, lower the requirements of carrier film and thus achieving cost saving as well. The present invention also provides the material selection of the intermediate protective layer and the synthesis of the material. The present invention also provides composition and synthesis of a carboxyl group-containing film-forming polymeric binder, free-radical photoinitiator, addition-polymerizable multi-functional monomers, and plasticizer in addition to a thermal stabilizer in the composition of negative-working dry-film photoresist.

The present invention provides the composition and preparation method of the double coated negative-working dry-film photoresist:

The present invention provides the double coated negative-working dry-film photoresist, which consists of flexible carrier film, flexible cover film, photopolymerizable composition layer, and intermediate protective layer. The character is as following:

In the present invention an aqueous soluble polymeric layer is coated as an intermediate protective layer between the carrier film and photoresist layer, the intermediate protective layer is colorless and transparent, soluble in the developing solution, processes good adhesion with both photoresist layer and the carrier film to ensure the quality of the photoresist in the manufacture process. Most important is that the adhesion between the intermediate protective layer and the photoresist layer is larger than that between the intermediate protective layer and the carrier film, so that in the process of removing the carrier thin film the intermediate protective layer is staying with the photoresist layer. The intermediate protective layer must possesses low oxygen permeability so that after removing the carrier film the intermediate protective layer covered on the photoresist layer can prevent oxygen to permeate into the photoresist layer and further prevent the inhibition of UV radiation initiated radical polymerization in the photoresist composition by oxygen in the exposing stage.

The polymeric material for the intermediate protective coating layer in the present invention is aqueous soluble, and also can be soluble in organic solvent, it must possesses excellent film-formation property. The most preferable material is polyvinyl alcohol (PVA) or carboxyl-containing polymers.

PVA is commercial available, require alcoholysis degree varies from 60-100%, most preferable alcoholysis degree from 70-90%; the weight average molecular weight varies from 20,000-150,000, most preferable weight average molecular weight from 30,000-120,000. An aqueous solution of PVA can be used in the coating process of the intermediate protective layers.

The carboxyl-containing polymeric material also can be used for the intermediate protective layer. The binder used in the present invention (see below) can be used for the intermediate protective layer. Aqueous solution of the binder can be prepared by dissolving the binder solid from suspension polymerization in water. The pH is required to be adjusted to 8-10 and the total solids to be adjusted to 5-15% for the coating solution. The solid binder can also be prepared by solution polymerization in 2-butanone and can be used directly to the coating as a total solids of 25-40%.

The polymeric material for the intermediate protective coating layer can also be selected from maleic anhydride/styrene copolymer salt aqueous solution or half-ester of maleic anhydride/styrene copolymer salt aqueous solution, including but not limited to sodium, potassium, lithium, and ammonium salt. The ratio of maleic anhydride and styrene in the copolymer varies from 1.2:1.0 to 0.8-1.0. The weight average molecular weight of maleic anhydride/styrene copolymer salt aqueous solution or half-ester of maleic anhydride/styrene copolymer salt aqueous solution varies from 40,000-150,000, preferred from 50,000-100,000. The ester of half-ester of maleic anhydride/styrene copolymer includes methyl, ethyl, propyl, butyl, pentyl, and hexyl ester.

The polymeric material for the intermediate protective coating layer can also be selected from other aqueous-soluble polymeric materials, such as cellulosic ether, carboxyl methyl cellulose, carboxyl methyl starch, hydroxyl ethyl cellulose, polyacrylamide, and polyvinylpyrrolidone.

According to the present invention there is as aqueous-developable negative-working dry-film photoresist composition, comprises a specific polymeric binder, free-radical photoinitiator, addition-polymerizable monomer, thermal polymerization inhibitor, plasticizer, adhesion promoting agent and dye. Based on the total weight of the dry-film photoresist composition, the amount of polymeric binder varies from 40-70%, more preferably from 50-60%; the amount of photoinitiator varies from 0.5-10%, more preferably from 3-7%; the amount of addition-polymerizable monomer varies from 5-40%; more preferably from 15-35%; the amount of plasticizer varies from 2-30%, more preferably from 9-15%; the amount of thermal polymerization inhibitor varies from 0.003-0.04%, more preferably from 0.01-0.02%.

The carboxyl group containing film-forming polymeric binder useful in accordance with this invention is prepared from two or more vinyl type monomers. The first type of monomer is alpha, beta ethylenically unsaturated carboxyl group containing monomer having 3-15 carbon atoms, which make the binder soluble in aqueous media. Example of useful vinyl type monomers are cinnamic acid, crotonic acid, sorbic acid, acrylic acid, methacrylic acid; acrylic acid and methacrylic acid are preferred. The second type of monomer is half ester of these acids. The ester group is (i) C₁-C₈ alkyl, linear or branched (ii) hydroxyl containing C₁-C₈ alkyl, linear or branched (iii) C₁-C₄ substituted phenyl, C₁-C₄ alkyl is linear or branched, phenyl is alkyl mono or multi substituted. The carboxyl group containing film-forming polymeric binder useful in accordance with this invention is thus prepared from one or more than one acid of the first type of monomer and one or more than one second type of half ester monomer.

The binder useful in this invention can be prepared from solution radical polymerization with weight average molecular weight varies more preferably from 20,000-200,000, most preferably from 40,000-100,000. Molecular weigh of the binder is measured by Gel Permeation Chromatography (GPC), calibrated with polystyrene standard. Tg of the binder varies from 80° C.-110° C., most preferably from 95° C. to 110° C. In the preparation of the binder, based the total weight of the binder solution, the amount of monomer varies from 15-50%, more preferred from 20-45%, and most preferred from 25-40%. The solvent used in the binder preparation can be selected from organic solvent with boiling point of below 120° C., include but not limited to acetone, butanone, 2-pentanone, ethyl acetate, cyclohexane, benzene, toluene, propylene glycol mono methyl ether acetate, and halogen substituted alkanes.

The binder useful in this invention can also be prepared from suspension polymerization. The binder solid obtained from the suspension polymerization can be dissolved in these solvents to form binder solution.

The plasticizer useful in the accordance with the present invention can be any plasticizer used in dry-film photoresist composition, which is apparent to those skilled in the art.

The free-radical photoinitiator useful in accordance with this invention is a conventional photoinitiator activated by actinic radiation that is thermally inactive below about 185° C. Examples of useful photoinitiators are aromatic ketones, such as benzophenone, 2,4-dimethoxyacetophenone, Michler's ketone, 4,4′-bis(diehylamino)benzophenone, 2-tert-butylanthraquinone, 2-ethyl thioxanthone, benzoin alkyl ether. Other useful photoinitiators will be apparent to those skilled in the art.

The polyfunctional addition-polymerizable monomer that finds application in the subject invention contains at least 2, preferably 2 to 4, more preferably 2 to 3 ethylenic double bonds, having at least 2 ethylenic double bonds makes the monomer polyfunctional, capable of cross-linked polymerization.

Suitable monomers include alkylene or polyalkylene glycol diacrylate. Monomers containing vinylidene groups conjugated with ester linkage are particularly suitable. Illustrative examples include but not limited to ethylene diacrylate, diethylene glycol acrylate, glycerol diacrylate, glycerol triacrylate, 1,3-propanediol dimethacrylate, 1,2,4-butanetriol trimethacrylate, 1,4-benzenediol dimethacrylate, 1,4-cyclohexanediol diacrylate, pentaerythritol tri- and tetraacrylate, pentaerythritol tri- and tetramethacrylate, tetraethylene glycol dimethacrylate, trimethylolpropane trimethacrylate, triethylene glycol diacrylate, tetraethylene glycol diacrylate, pentaerythritol triacrylate, Trimethylol propane triacrylate, pentaerythritol tetraacrylate, 1,3-propanediol diacrylate, 1,5-pentanediol dimethacrylate, and the bis-acrylates and bis-methacrylates of polyethylene glycols, polypropylene glycols, and copolymers thereof of number average molecular weight from about 100 to about 500. Other useful polymerizable monomers will be apparent to those skilled in the art.

The thermal polymerization inhibitor used in accordance with this invention prevents thermal polymerization during drying and storage. Examples of useful thermal polymerization inhibitors are p-methoxy-phenol, hydroquinone, alkyl or aryl-substituted hydroquinones and quinones, tertbutyl catechol, pyrogallol, copper resinate, β-naphthol, 2,6-di-tert-butyl-p-cresol, 2,2′-methylene-bis(4-ethyl-6-t-butylphenol), p-tolylquinone, chloranil, aryl phosphites, and aryl alkyl phosphites. Other useful thermal polymerization inhibitors will be apparent to those skilled in the art.

The photopolymerizable composition of this invention optionally includes additives well known in the art of photopolymerizable compositions, such as leuco (i.e. printout) dyes, background dyes, and adhesion promoters. Other optional additives will be apparent to those skilled in the art.

The photoresist solution of this invention is prepared by mixing the various components in the binder solution. The aqueous or organic solution of polymer materials is evenly coated onto a carrier film by coater or coating head, and dried in an oven to form the intermediate protective layer. The aforementioned photoresist solution is then coated onto the intermediate protective layer, and the cover film is attached after drying in an oven to form the dry film photoresist of the instant invention. A special multi-layer coating head can also be used to coat the aqueous or organic solution of polymer materials and the photoresist solution onto a carrier film, with the intermediate protective layer under the photoresist layer, then the cover film is attached after drying in an oven to form the dry film photoresist of the instant invention, as shown in FIG. 2.

The thickness of the polymer layer varies generally from 0.5-10 μm, preferably from 1-2 μm. The thickness of the photoresist varies from 10-100 μm, preferably from 12-80 μm. The thickness of carrier film and cover film varies preferably from 15-25 μm.

Both the carrier film and cover film are made of film-forming polymer materials, without requirements of optical transparency and colorlessness.

The dry film photoresist of the instant invention is used in the manufacture of printed circuit boards. For traditional dry film photoresist, the photoresist layer is applied to the copper clad substrate together with the carrier film by hot roll lamination, as shown in FIG. 3. The negative with specific image is placed on the carrier film, and then the photoresist is exposed to ultraviolet light or laser through the negative and carrier film. The carrier film cannot be removed before the exposure. Generally, the amount of actinic radiation is about 20 mJ/cm2˜60 mJ/cm2, with precise amounts depending on factors such as the specific compositions and the thickness of the dry film.

The dry film photoresist of the instant invention is applied to the copper clad substrate together with the carrier film by the same way of hot roll lamination. As shown in FIG. 4, there is the intermediate protective layer between the photoresist layer and the carrier film. Unlike traditional dry film, the carrier film is firstly removed, and then the patterned negative is placed on the intermediate protective layer, The photoresist is exposed to ultraviolet light or laser through the negative and the intermediate protective layer, rather than carrier film. The amount of actinic radiation is the same as the corresponding traditional dry film.

In the present invention, the functions of the extra coating of polymer materials (intermediate protective layer), are to cut off oxygen penetrate to the photoresist composition and to also prevent the adhesion between the dry film photoresist and the negative. When applying the dry film photoresist of this invention, the carrier film can be removed before exposure; therefore it's not necessary to be completely transparent and colorless, so as to greatly reduce the cost of the carrier film. More importantly, when using the traditional dry film photoresist, its resolution is reduced due to light scattering of the carrier film of about 15-25 μm. As for the dry film photoresist of this invention, it is exposed to actinic radiation through the intermediate protective layer of only 1-2 μm after removing the carrier film, so that its resolution is improved substantially.

After exposure, the dry film photoresist is developed together with the intermediate protective layer. In general, the developing solutions, useful in removing the intermediate protective layer and unexposed part of the photoresist, are alkali metal salts of weak acids, e.g. sodium carbonate and bicarbonate, and alkaline metal phosphates and pyrophosphates. Sodium carbonate is preferred. It can also be developed by a proprietary aqueous alkaline develop solution. The circuit board can be submerged in the developing solution or, preferably, the solution is high pressure sprayed on the board.

The copper clad substrate is any known copper/dielectric laminate used in circuit board manufacture, such as a copper clad board of fiberglass reinforced epoxy resin. Other useful dielectrics can be used in aforementioned copper clad substrate.

In general, the stripping solutions useful in removing the photopolymerized material in accordance with the instant invention are heated aqueous alkaline solutions. Generally, aqueous solutions of alkali metal hydroxide or proprietary alkaline stripping solutions are used. The temperature of stripping solution varies from 45-65° C., preferably from 50-55° C., washing the substrate to remove the photopolymerized material.

### DESCRIPTION OF FIGURES

FIG. 1. Finished product of traditional dry film photoresist

FIG. 2. Finished product of dry film photoresist with the intermediate protective layer

FIG. 3. Lamination of traditional dry film photoresist

FIG. 4. Lamination of dry film photoresist with the intermediate protective layer:

1. Supporting layer 1 (carrier film); 2. Supporting layer 2 (cover film); 3. Photoresist layer; 4. Intermediate protective layer; 5. Copper clad; 6. Substrate; 7. Hot roll.

### DESCRIPTION OF THE PREFERRED EMBODIMENTS

In order to more clearly describe the present invention, the following non-limiting examples are provided. All parts and percentages in the examples are by weight unless indicated otherwise.

### Example 1

### Suspension Polymerization of Polyacrylic Acid/Polyacrylate Copolymer

In a four-neck, round-bottom 500 ml flask, equipped with condenser, mechanical stirrer, dropping funnel, nitrogen gas inlet and outlet, is charged with 300 g of de-ionized water. Agitation is started at a rate of 200 rpm with heating and passing nitrogen from the bottom of the flask. 4 g of pre-prepared METHOCEL, Hydroxypropyl Methyl Cellulose and Hydroxypropyl Cellulose (manufactured by Dow Chemical, 1:1 by weight, 4% solid content) is charged into the flask. When the temperature has reached 65° C., switch the nitrogen inflow from bottom to top blanket cover. 80 g of a monomer mixture (methacrylic acid 4 g, methyl methacrylate 74 g, n-butyl methacrylate 2 g) is added through the dropping funnel evenly over a 10 minute period. At the same time, 5 g of azodiisobutyronitrile (AIBN) solution in isopropanol (6%) is added over a 10 minute period via a syringe pump. The temperature from 63-66° C. is maintained with stirring rate at 200 rpm for 6 hours. Then 5 g of AIBN solution in acetone (5%) is added through the syringe pump and the temperature is maintained from 63-66° C. for three hours. The heating is turned off and once the temperature dropped to 30° C., turned off the agitation. Filtration of the reaction mixture is carried out, washing the white solid obtained with de-ionized water (150 ml×3). Finally the white solid is dried in a vacuum oven at 100° C. for 3 hours. A white granulate solid is obtained (78.4 g, yield of 98.0%) with Tg of 96° C. (DSC).

### Example 2

### Solution Polymerization of Polyacrylic Acid/Polyacrylate Copolymer

In a four-neck, round-bottom 500 ml flask, equipped with condenser, mechanical stirrer, dropping funnel, nitrogen gas inlet and outlet, is charged with 250 g of methyl ethyl ketone (MEK). Agitation is started at a rate of 100 rpm with heating and passing nitrogen from the bottom of the flask. When the temperature has reached 75° C., switch the nitrogen inflow from bottom to top blanket cover. 115 g of a monomer mixture (methacrylic acid 5 g, methyl methacrylate 108 g, ethyl acrylate 2 g) is added through the dropping funnel evenly over a 120 minute period. At the same time, 10 g of AIBN solution in MEK (4%) is added over a 120 minute period via a syringe pump with an agitation rate from 100-150 rpm and temperature at 75-80° C. 5 g of AIBN solution in MEK (5%) is added every 3 hours. The temperature at 75-80° C. is maintained during the AIBN addition and another 9 hours after the last AIBN addition. Then the heating is turned off and a viscous solution is poured out from the flask when the temperature dropped to 30° C. Final product: Tg, 96° C.; total solids, 30.5%.

### Example 3

### Preparation of the Photosensitive Material Coating Solution

The photosensitive material coating solution is prepared according to the following formulation in Table 1.

TABLE 1

| | |
|---|---|
| Binder 1 (from Example 1) | 24.52 |
| MEK | 53.22 |
| Ethoxylated Bisphenol A Dimethylacrylate | 15.53 |
| Ethoxylated Trimethylolpropane Triacrylate | 4.10 |
| 2-ethylhexyl p-dimethylaminobenzonate | 1.51 |
| 2-Isopropyl Thioxanthone | 0.41 |
| Triethyl Citrate | 1.5 |
| Butylated Hydroxytoluene | 0.21 |

Firstly Binder 1 is dissolved in MEK. The binder is added to MEK with the agitation of a propeller mixer. The materials in Table 1 are added to the binder MEK solution with the agitation by the propeller mixer at about 600 rpm for about 60-90 minutes to a uniform solution. Then the mixture solution is centrifuged for 3 minutes to remove air bubbles.

### Example 4

### Preparation of the Photosensitive Material Coating Solution

The photosensitive material coating solution is prepared according to the following formulation in Table 2.

TABLE 2

| | |
|---|---|
| Binder 2 (from Example 2) | 73.80 |
| Ethoxylated Bisphenol A Dimethylacrylate | 20.51 |
| Poly (Vinyl acetate-co-Vinyl chloride-co-Vinyl ester) | 0.25 |
| Benzophenone | 2.31 |
| 2-Isopropyl Thioxanthone | 0.36 |
| Triethyl Citrate | 2.51 |
| Butylated Hydroxytoluene | 0.26 |

The materials in Table 2 are uniformly mixed by a propeller mixer at about 600 rpm for about 60-90 minutes. Then the mixture solution is centrifuged for 3 minutes to remove air bubbles.

### Examples 5-6

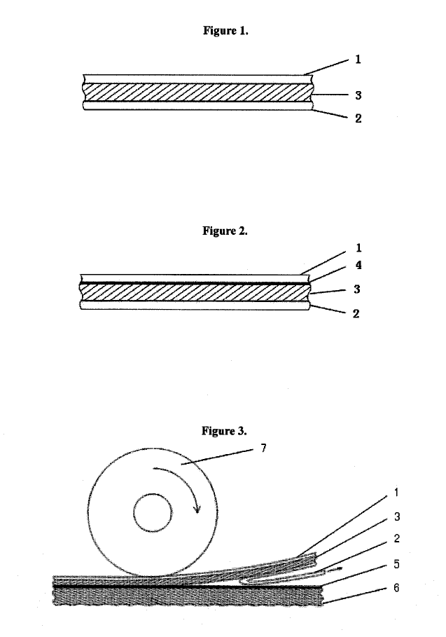

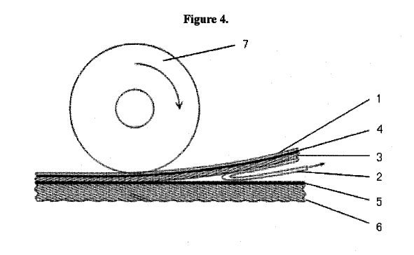

The dry film photoresists are made using the mixture solution from Example 3 and Example 4 respectively, as illustrated in FIG. 1. Drawdowns are made of the photosensitive materials on a polyester film of about 16 μm, and then dried in an oven at 100° C. for 3-6 minutes. Then drawdowns are laminated to a degreased and scrubbed double-sided copper panel (56.7 g copper on a dielectric base) having a thickness of 0.79 mm on a hot-roll laminator at a temperature of about 121° C., a pressure of 2.1 kg/cm2, and a speed of 121.9 cm/min. The panels are exposed imagewise through a negative at an exposure corresponding to Stouffer Step 6-7 (using a 21 Stouffer Step Guide). The panels are held for 15 minutes and the passed through a developer to give a 50% breakpoint in a developing solution of 0.90 wt % aqueous sodium carbonate monohydrate at a temperature of about 35° C., a top spray pressure of 1.41 kg/cm2, and a rinse pressure of about 1.41 kg/cm2.

The performance of the dry film photoresist is evaluated by measuring photoresist resolution, adhesion and reproduction on developed panels. The resolution can be read out directly, the smaller value indicates the better resolution. The reproduction is the measurement difference between the negative and the sample panel, based on the line of 150 μm width (l) and spacing (s), the smaller value indicates the better reproduction. The adhesion is visually checked by the adherence of a series of lines with 250 μm spacing. The narrower line with the same corresponding size adherent to the panel indicates the better adhesion. The performance items for each example are listed in the following Table 3.

TABLE 3

| | Photoresist | Resolution | Adhesion | Reproduction |
|---|---|---|---|---|
| Example | thickness (μm) | (mil) | (l/s, μm) | (mil) |
| 5 | 30 | 1.1-1.5 | 50/250 | 0 |
| 6 | 31 | 1.3-1.5 | 60/250 | 0 |

### Examples 7-8

The photosensitive material layer is prepared as formulations in Table 1 and Table 2. The intermediate protective layer is 15 wt % to 20 wt % of BP17 (ChangChun Group, Taiwan) aqueous solution. This material is a moderately viscous, water soluble and partially hydrolyzed polyvinyl alcohol polymer, with a thickness of 1-2 μm.

The dry film photoresists are made as illustrated in FIG. 2. Drawdowns are made of the intermediate protective layer on a polyester film of about 16 μm, and then dried in an oven at 100° C. for 3-6 minutes. After cooling, drawdowns are made of the photosensitive material layer directly on the intermediate protective layer, and then dried in an oven at 100° C. for 3-6 minutes. Then drawdowns are laminated to a degreased and scrubbed double-sided copper panel (56.7 g copper on a dielectric base) having a thickness of 0.79 mm on a hot-roll laminator at a temperature of about 121° C., a pressure of 2.1 kg/cm2, and a speed of 121.9 cm/min. After feeling of the polyester film, the panels are exposed imagewise through a negative at an exposure corresponding to Stouffer Step 6-7 (using a 21 Stouffer Step Guide). The panels are held for 15 minutes and the passed through a developer to give a 50% breakpoint in a developing solution of 0.90 wt % aqueous sodium carbonate monohydrate at a temperature of about 35° C., a top spray pressure of 1.41 kg/cm2, and a rinse pressure of about 1.41 kg/cm2.

The performance for each example is listed in the following Table 4.

TABLE 4

| | Intermediate | Photoresist | | | Repro- |
|---|---|---|---|---|---|
| | thickness | thickness | Resolution | Adhesion | duction |
| Example | (μm) | (μm) | (mil) | (l/s, μm) | (mil) |
| 7 | 1.2 | 30 | 0.5-1.0 | 30/250 | 0 |
| 8 | 1.5 | 30 | 0.9-1.2 | 50/250 | 0 |

In the experiments, there is little difference of exposure energy required to achieve the same exposure degree. The intermediate protective layer works well to cut off oxygen and it's not adherent to the negative, so it can completely replace the relatively thicker polyester film in the process of exposure with significant improvement in the resolution.

### Examples 9-10

Repeat the process of Example 7-8. The intermediate protective layer is replaced by the MEK solution of the binder from Example 1.

The performance items for each example are listed in the following Table 5.

TABLE 5

| | Intermediate | Photoresist | | | Repro- |
|---|---|---|---|---|---|
| | thickness | thickness | Resolution | Adhesion | duction |
| Example | (μm) | (μm) | (mil) | (l/s, μm) | (mil) |
| 9 | 1.3 | 31 | 0.6-1.0 | 30/250 | 0 |
| 10 | 1.2 | 31 | 0.9-1.1 | 50/250 | 0 |

In the experiments, there is little difference of exposure energy required to achieve the same exposure degree. The intermediate protective layer works well to cut off oxygen and it's not adherent to the negative, so it can completely replace the relatively thicker polyester film in the process of exposure with significant improvement in the resolution.

### Examples 11-12

Repeat the process of Example 7-8. The intermediate protective layer is replaced by the 10%-15% sodium carbonate solution of the binder from Example 1.

The performance items for each example are listed in the following Table 6.

TABLE 6

| | Intermediate | Photoresist | | | Repro- |
|---|---|---|---|---|---|
| | thickness | thickness | Resolution | Adhesion | duction |
| Example | (μm) | (μm) | (mil) | (l/s, μm) | (mil) |
| 11 | 1.2 | 30 | 0.8-1.0 | 30/250 | 0 |
| 12 | 1.3 | 31 | 0.9-1.1 | 50/250 | 0 |

In the experiments, there is little difference of exposure energy required to achieve the same exposure degree. The intermediate protective layer works well to cut off oxygen and it's not adherent to the negative, so it can completely replace the relatively thicker polyester film in the process of exposure with significant improvement in the resolution.

### Examples 13-14

Repeat the process of Example 7-8. The intermediate protective layer is prepared by polyacrylic acid/polyacrylate copolymer resin (total solids of 30.5 solution in MEK) synthesized as in Example 2.

The performance for each example is listed in the following Table 7.

TABLE 7

| | Intermediate | Photoresist | | | Repro- |
|---|---|---|---|---|---|
| | thickness | thickness | Resolution | Adhesion | duction |
| Example | (μm) | (μm) | (mil) | (l/s, μm) | (mil) |
| 13 | 1.5 | 31 | 0.5-0.9 | 30/250 | 0 |
| 14 | 1.5 | 30 | 0.7-1.0 | 40/250 | 0 |

In the experiments, there is little difference of exposure energy required to achieve the same exposure degree. The intermediate protective layer works well to cut off oxygen and it's not adherent to the negative, so it can completely replace the relatively thicker polyester film in the process of exposure with significant improvement in the resolution.

1-7. (canceled)

8. A double coated negative-working dry-film photoresist comprising a flexible carrier film, a flexible cover film, a photoresist composition layer, and an intermediate protective layer wherein:
An intermediate protective layer is positioned between the flexible carrier film and the photoresist composition layer, which intermediate protective layer is transparent, colorless and soluble in developer solution of photoresist composition layer, wherein the photoresist composition comprises polyvinyl alcohol having a weight average molecular weight of 20,000-150,000 with an alcoholysis of 60-100% or polymeric material with carboxyl groups, and has a thickness of about 0.5-10 micrometer;
Wherein the part of the photoresist composition layer exposed under UV light is insoluble in basic aqueous developing solution but that part not exposed under UV light is soluble to form images, such composition comprising a polymeric binder, free-radical photoinitiator, addition-polymerizable monomer, thermal polymerization inhibitor, and optimally additives, such as dye, plasticizer, and adhesion promoter and has a thickness of 10-100 micrometers; and
Wherein both the flexible carrier film and the cover film are made from polymeric material which is optimally transparent and colorless.

9. A photoresist composition comprising the double coated negative dry-film photoresist of claim 1, wherein the polymeric binder is a carboxyl-containing polymeric material with a weight average molecular weight of 20,000-200,000, and a Tg of 80-120° C.

10. A photoresist composition comprising the double coated negative dry-film photoresist of claim 1, wherein the polymeric binder is a carboxyl-containing polymeric material with a weight average molecular weight of 40,000-100,000, and a Tg of 95-110° C.

11. A photoresist composition comprising the double coated negative dry-film photoresist of claim 1, wherein the polymeric binder is a polymer of at least by two monomers, the first monomer being a carboxyl-containing alpha, beta unsaturated polymer with at least 3-15 carbon-atoms, such as cinnamic acid, butenic acid, sorbic acid, acrylic acid, and methacrylic acid and the second monomer being a ester of the corresponding acid of the first monomer, wherein the ester part is a (1) linear or branch C₁-C₈ alkyl; (2) linear or branch C₁-C₈ hydroxyl-containing alkyl; (3) phenyl mono-substituted or multi-substituted with linear or branch C₁-C₄ alkyl; wherein the polymeric binder is capable of forming a thin-film, is a polymer of one or more than one monomers of the first monomer and one or more monomers of the second monomer.

12. A composition comprising the double coated negative dry-film photoresist of claim 1, wherein the polyvinyl alcohol of the intermediate protective layer has a weight average molecular weight of 30,000-120,000 and an alcoholysis of 70-90%.

13. A composition comprising the double coated negative dry-film photoresist of claim 1, wherein the carboxyl-containing intermediate protective layer material comprising the same polymeric binder as the composition of the photoresist composition layer.

14. A composition comprising the double coated negative dry-film photoresist of claim 1, wherein the intermediate protective layer has a thickness of 1-2 micrometers; and the photoresist composition layer has a thickness of 12-80 micrometers.
